(19) United States
(12) Patent Application Publication
(10) Pub. No.: US 2008/0315407 A1
(43) Pub. Date: Dec. 25, 2008

(54) THREE-DIMENSIONAL CIRCUITRY FORMED ON INTEGRATED CIRCUIT DEVICE USING TWO-DIMENSIONAL FABRICATION

(75) Inventors: Lawrence Douglas Andrews, JR., Los Gatos, CA (US); Simon J.S. McElrea, Scotts Valley, CA (US); Terrence Caskey, Santa Cruz, CA (US); Scott McGrath, Scotts Valley, CA (US); Yong Du, Cupertino, CA (US)

Correspondence Address: HAYNES BEFFEL & WOLFELD LLP, P O BOX 366, HALF MOON BAY, CA, 94019, US

(73) Assignee: Vertical Circuits, Inc., Scotts Valley, CA (US)

(21) Appl. No.: 12/143,157

(22) Filed: Jun. 20, 2008

Related U.S. Application Data
(60) Provisional application No. 60/945,274, filed on Jun. 20, 2007.

(51) Int. Cl. H01L 23/482; G01R 31/26; H01L 21/50; H01L 23/00

(52) U.S. Cl. 257/735; 324/765; 438/113; 257/777; 257/E23.014; 257/E21.499

(57) ABSTRACT

Stackable integrated circuit devices include an integrated circuit die having interconnect pads on an active (front) side, the die having a front side edge at the conjunction of the front side of the die and a sidewall of the die, and a back side edge at the conjunction of back side of the die and the sidewall; the die further includes a conductive trace which is electrically connected to an interconnect pad and which extends over the front side edge of the die. In some embodiments the conductive trace further extends over the sidewall, and, in some such embodiments the conductive trace further extends over the back side edge of the die, and in some such embodiments the conductive trace further extends over the back side of the die. One or both of the die edges may be chamfered. Also, methods for making such a device. Also, assemblies including such a device electrically interconnected to underlying circuitry (e.g., die-to-substrate); and assemblies including a stack of at least two such devices interconnected die-to-die, or such a stack of devices electrically interconnected to underlying circuitry. Also, apparatus and methods for testing such a die.

### CROSS-REFERENCE TO RELATED APPLICATION

This application claims priority in part from L. D. Andrews, Jr. U.S. Provisional Application No. 60/945,274, titled “Three-dimensional circuitry formed on integrated circuit device using two-dimensional fabrication”, which was filed Jun. 20, 2007, and which is hereby incorporated by reference herein.

### BACKGROUND

This invention relates to electrical interconnection of integrated circuit chips and, particularly, to stackable integrated circuit devices suited for vertical interconnection. [0003] Interconnection of die with one another in a stack of die (“die-to-die”) or of a die or a die stack with a substrate (“die-to-substrate”) presents a number of challenges. For example, the integrated circuitry is situated on an “active side” of the die, and exposed pads are situated on the active side of the die for electrical interconnection with other die or with a substrate. When die are stacked, one die in the stack may obscure the pads on another die, making them inaccessible for interconnection, particularly where die having the same or similar dimensions are stacked one over another.

Various kinds of die interconnection have been proposed, including among others flip-chip interconnect, wire bond interconnect, and tab bond interconnect.

Where wire bond interconnect is employed in a stacked die assembly, the wire bonds may be formed to connect pads on the active side of a first die before an additional die is stacked over it. A spacer is typically provided upon the active side of the first die, to prevent interference by the second die with the wire loops on the first die.

Approaches to vertical interconnection of die, other than by wire bonds, bumps, or tabs are described, for example, in U.S. Pat. No. 5,675,180 and its progeny; and, for example, in U.S. Pat. No. 7,215,018 and, for example, in U.S. application Ser. No. 11/097,829.

Particularly, for example, U.S. application Ser. No. 11/097,829 describes “off-die” interconnection, employing interconnection terminals electrically connected to peripheral sites on the die and projecting beyond the die edge; interconnection of the die is made by electrically conductive polymer elements into which the projecting parts of the interconnection terminals extend.

Some die as provided have die pads along one or more of the die margins, and these may be referred to as peripheral pad die. Other die as provided have die pads arranged in one or two rows near the center of the die, and these may be referred to as center pad die. The die may be “rerouted” to provide a suitable arrangement of interconnect pads at or near one or more of the edges of the die.

### SUMMARY

In a general aspect the invention features a stackable integrated circuit device, including an integrated circuit die having interconnect pads on an active (front) side, the die having a front side edge at the conjunction of the front side of the die and a sidewall of the die and a back side edge at the conjunction of back side of the die and the sidewall; and a conductive trace which is electrically connected to an interconnect pad and which extends over the front side edge of the die. In some embodiments the conductive trace further extends onto the sidewall, and, in some such embodiments the conductive trace further extends over the back side edge of the die, and in some such embodiments the conductive trace further extends onto the back side of the die.

In some embodiments the die further includes a trace at the back side of the die, and in some such embodiments the backside trace extends over the back side edge.

In some embodiments the die has a chamfered edge at the conjunction of the front side of the die and a sidewall of the die; the conductive trace extends over the chamfer at the chamfered edge of the die and in some embodiments the conductive trace further extends over the sidewall.

In some embodiments the die further includes a back edge chamfer at the conjunction of the back side of the die and a sidewall of the die; and in some such embodiments the conductive trace extends over the back edge chamfer. In some such embodiments the die further includes a conductive trace at the back side of the die, and in some such embodiments the backside trace extends over the back edge chamfer.

In some embodiments the die includes both a front edge chamfer and a back edge chamfer at one of more of the sidewalls, and a conductive trace which is electrically connected to an interconnect pad extends over the front edge chamfer, the sidewall, the back edge chamfer and the die backside.

In some embodiments the die further includes a dielectric between the conductive trace and the chamfer; in some embodiments the die further includes a dielectric between the conductive trace and the sidewall. In some embodiments the portion of the conductive trace over the chamfer and the conductive trace over the sidewall comprise a different material; in other embodiments the portion of the conductive trace over the chamfer and the conductive trace over the sidewall comprise a similar material, or the same material.

In some embodiments the interconnect pad is one of a row of pads arranged near a centerline of the die; in other embodiments the interconnect pad is one of a row of pads arranged near an edge of the die. In some such embodiments the conductive trace extends to a chamfer at a die edge that is parallel to the row of pads; in some embodiments the conductive trace extends to a chamfer at a die edge other than a die edge that is parallel to the row of pads.

In another aspect the invention features a test socket for testing a stackable integrated circuit device as described above, including an electrically insulative base and electrically conductive contacts, each arranged to make electrical contact with a portion of the conductive trace at the chamfer, the contacts being connected to test circuitry.

In another aspect the invention features a method for testing a stackable integrated circuit device as described above, by providing a test socket as described above; moving the device toward the test socket so that the contacts make electrical contact with respective traces at the chamfer; and activating the test circuitry.

In another aspect the invention features a method for making a stackable integrated circuit device, by: providing a wafer including a plurality of semiconductor die each having edges bounded by saw streets and each having an interconnect pad on an active (front) side; forming a trench in the street, the trench defining die edges and die sidewalls; and forming an electrically conductive trace that is electrically connected to the pad and that extends to one of the edges.

In some embodiments the trench has a generally rectangular sectional profile, so that the resulting die sidewalls are generally perpendicular to the plane of the die front side (the inside angle formed at the conjunction of the die front side and the resulting sidewalls is about 90°); in other embodiments the trench has a generally trapezoidal sectional profile (with the longer parallel side at the die front side), so that the inside angle formed at the conjunction of the die front side and the resulting sidewalls is greater than 90°.

In some embodiments the electrically conductive trace is formed to extend over the edge, and in some such embodiments the electrically conductive trace is formed to extend over the edge and onto the die sidewall.

In some embodiments the method further includes forming an electrically conductive sidewall trace that is electrically connected to the conductive trace over the edge and that extends over the sidewall.

In another aspect the invention features a method for making a stackable integrated circuit device, by: providing a wafer including a plurality of semiconductor die each having edges bounded by saw streets and each having an interconnect pad on an active (front) side; forming a chamfer at each die edge; forming an electrically conductive trace that is electrically connected to the pad and that extends over one of the chamfers; and cutting the wafer to form a sidewall and to singulate the die. In some embodiments the method further includes forming an electrically conductive sidewall trace that is electrically connected to the conductive trace over the chamfer and that extends over the sidewall.

In another aspect the invention features an assembly including a stack of devices as described above, interconnected die-to-die by a conductive element that is electrically connected to the conductive trace at the chamfer and/or at the sidewall on at least two of the stacked die.

In another aspect the invention features an assembly including a device or a stack of devices as described above, interconnected to underlying circuitry (for example in a substrate or a circuit board) by a conductive element that is electrically connected to the conductive trace at the chamfer and/or at the sidewall on the die or on at least one of the stacked die.

The assemblies according to the invention can be used for building computers, telecommunications equipment, and consumer and industrial electronics devices.

### BRIEF DESCRIPTION OF THE DRAWINGS

FIG. 1A is a diagrammatic sketch in a plan view showing the circuit side of a one-half portion of a semiconductor wafer.

FIG. 1B is a diagrammatic sketch in a plan view showing a portion of the wafer of FIG. 1A including the area of an integrated circuit chip.

FIGS. 2A and 2B through 8A and 8B are diagrammatic sketches showing stages in a process for making a stackable, vertically interconnectable integrated circuit chip according to an embodiment of the invention. The sketches in FIGS. 2A, 3A, 4A, 5A, 6A, 7A, 8A are in a plan view as in FIG. IA; the sketches in FIGS. 2B, 3B, 4B, 5B, 6B, 7B, 8B are in a transverse sectional view as indicated at 2B-2B, 3B-3B, 4B-4B, 5B-5B, 6B-6B, 7B-7B, 8B-8B in FIGS. 2A, 3A, 4A, 5A, 6A, 7A, 8A respectfully.

FIGS. 9A, 9B are diagrammatic sketches in a sectional view showing use of a test socket to test an integrated circuit chip according to an embodiment of the invention.

FIG. 10 is a diagrammatic sketch in a sectional view showing a stackable, vertically interconnectable integrated circuit chip according to another embodiment of the invention.

FIG. 11 is a diagrammatic sketch in a sectional view showing a stackable, vertically interconnectable integrated circuit chip according to another embodiment of the invention.

FIGS. 12, 13, 14 are diagrammatic sketches in sectional view showing stacked integrated circuit chip assemblies according to embodiments of the invention.

FIGS. 15, 16, 17 are diagrammatic sketches un a sectional view showing stages in a process for making a stackable, vertically interconnectable integrated circuit chip according to another embodiment of the invention.

FIGS. 18, 19, 20 are diagrammatic sketches un a sectional view showing stages in a process for making a stackable, vertically interconnectable integrated circuit chip according to another embodiment of the invention.

### DETAILED DESCRIPTION

The invention will now be described in further detail by reference to the drawings, which illustrate alternative embodiments of the invention. The drawings are diagrammatic, showing features of the invention and their relation to other features and structures, and are not made to scale. For improved clarity of presentation, in the FIGs. illustrating embodiments of the invention, elements corresponding to elements shown in other drawings are not all particularly renumbered, although they are all readily identifiable in all the FIGs. Also for clarity of presentation certain features are not shown in the FIGs., where not necessary for an understanding of the invention. For example, details of the circuitry within the die are omitted.

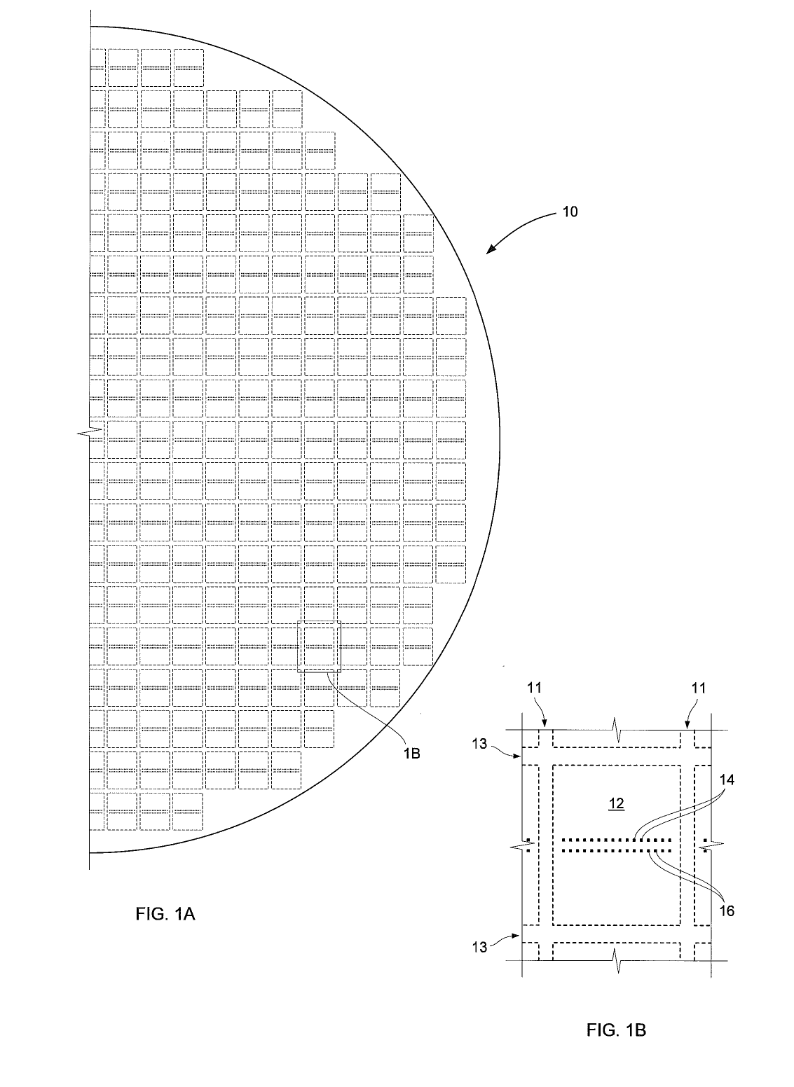

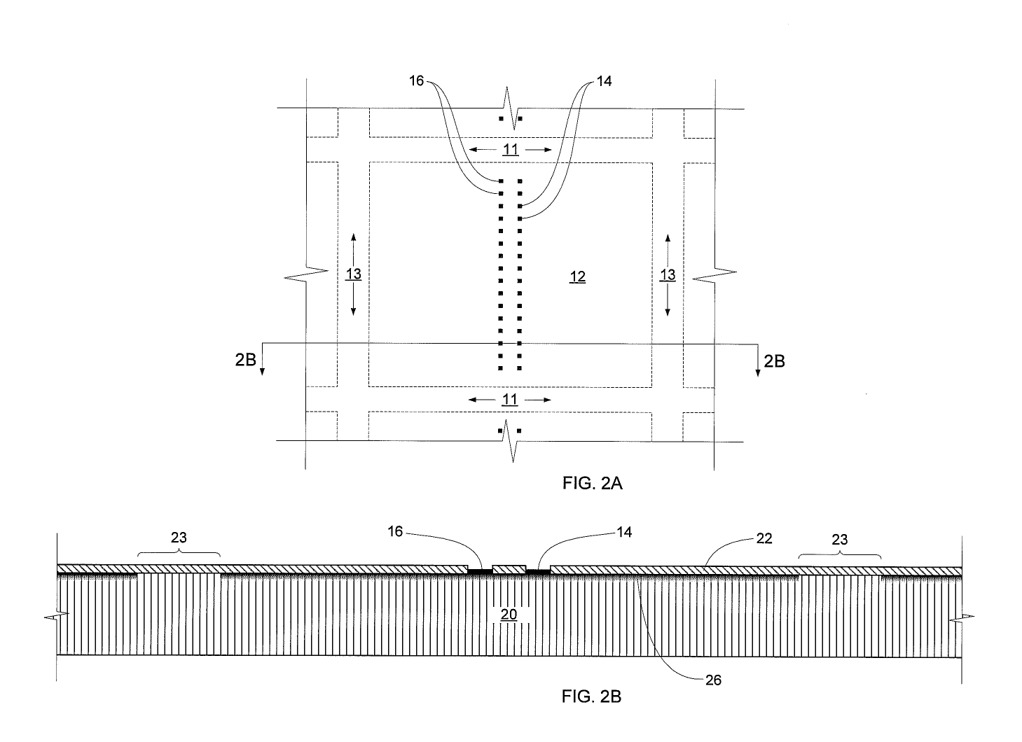

Turning now to FIG. 1A, there is shown in a diagrammatic plan view a half-portion of a semiconductor wafer 10, with the active side in view. A number of integrated circuit chips are formed on the wafer, one of which is indicated at 1B, and shown in greater detail in FIG. 1B. Referring to FIG. 1B, an active region 12 of a chip is shown, bounded by saw streets 11 and 13. Interconnect pads 14, 16 are arrayed in rows alongside a centerline of the active region of the chip 12 and, accordingly, the chips shown by way of example in FIGS. 1A, 1B are center-pad die. FIG. 2A shows a chip as in FIG. 1B, somewhat enlarged; and FIG. 2B shows a sectional view thru a portion of a wafer 20 as indicated at 2B-2B in FIG. 2A. The active region of the chip is indicated in the active side of the wafer at 26. A passivation layer 22 overlies the active region. Openings in the passivation layer 22 expose interconnect pads 14, 16. Active regions of the respective die are bounded by saw streets 23. The wafer may be thinned at this stage, or later, for example following a dicing procedure (as described below). The wafer may be thinned by supporting the wafer, for example on a backgrinding tape (not shown) applied to the active side, and grinding or polishing away a portion of the backside of the wafer. Whether backgrinding is performed at this stage or later, the wafer is supported, for example on a dicing tape (not shown) applied to the back side, for subsequent processing.

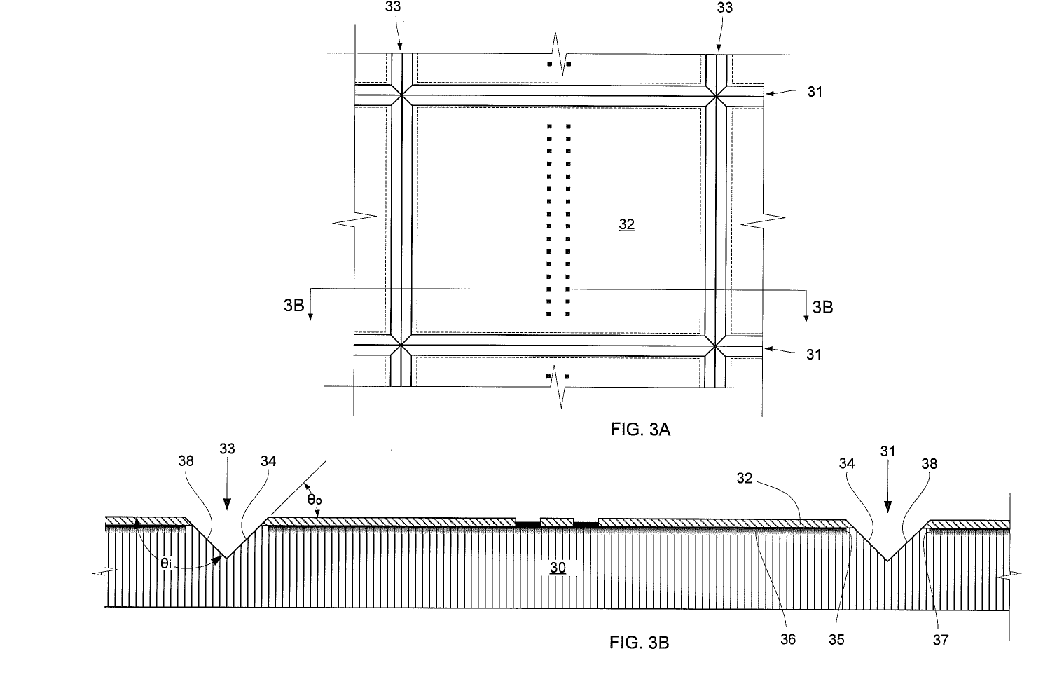

Grooves are then formed in the saw streets, as shown for example in FIGS. 3A, 3B. The grooves cut at least through the passivation layer 32 and into the semiconductor material of the wafer; the grooves are located so that they are outside the limits 35, 37 of the active regions (e.g., 36) of the respective chips, so that the grooves do not impact the onboard circuitry of the chips. The grooves 31, 33 have sloped sides 34, 38; that is, they are narrower at the bottom than at the top. In the example shown in the Figures the sides 34, 38 of the grooves are generally planar, and the plane of the grooves is at an outside angle θo less than 90°, for example about 45° (corresponding to an inside angle θi greater than 90°, for example about 135°) to the plane of the front side of the wafer. The grooves cut at least through the passivation layer 32 and into the semiconductor material 30 of the wafer. The grooves are located outside the limits 35, 37 of the active regions (e.g., 36) of the respective chips, so that the grooves do not impact the onboard circuitry of the chips.

The grooves may be formed by cutting, using for example a saw or grinding tool, or for example using a laser. Where the grooves are cut, more than one pass of the cutting tool may be employed. Or, the grooves may be formed by chemical etching, for example.

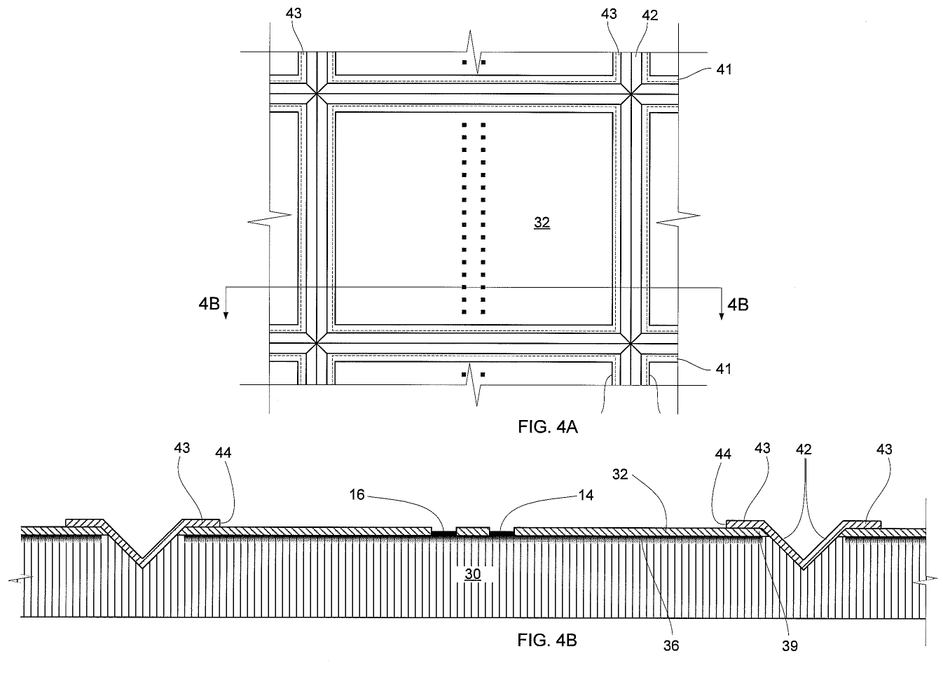

In a subsequent procedure a dielectric cap is formed in the grooves, with a result as shown for example in FIGS. 4A, 4B. A portion 42 of the cap overlies and conforms to the grooves, and accordingly is similarly sloped; and portions 43 of the cap overlap at least the edges 39 of the underlying passivation layer 32, but the cap does not cover the interconnect pads 14, 16.

The cap may be formed as a patterned layer of dielectric cap material. It may be formed by deposition and patterned removal (for example, by etch or by laser ablation), or by a patterned deposition (for example by direct write or print), or by a combination of patterned deposition and etch. Suitable materials for the dielectric cap material include, for example, a polymer that may be deposited or coated in a liquid phase, such as for example a polyimide/BT/epoxy/LCP that may or may not be directly photoimageable; a polymer that may be deposited in vapor phase, such as a parylene; or a liquid phase chemically deposited glass such as a sol-gel silica, for example.

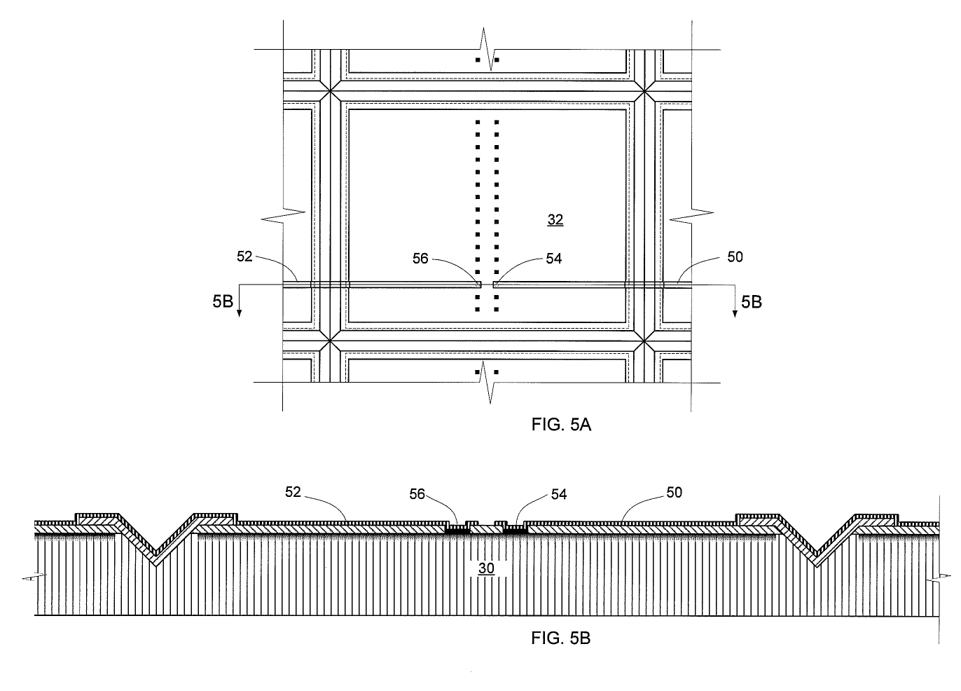

In a subsequent procedure patterned electrically conductive traces are formed, contacting the interconnect pads 14, 16 and extending into the capped grooves, with a result as shown for example in FIGS. 5A, 5B. As the Figures illustrate, conductive traces 50, 52 contact die pads 14, 16 at 54, 56, respectively, and extend into the capped grooves. Additional such traces (omitted from FIG. 5A) are formed in contact with other die pads and extend into the grooves.

The conductive traces may be formed of any of a variety of electrically conductive materials, including metals and metal alloys, conductive inks, and conductive epoxies, for example. The conductive traces may be formed by any of a variety of techniques, selected as appropriate according to the material. Metal traces (gold, aluminum, copper) can be formed by applying a metal film (for example by sputtering or evaporative deposition) or metallization such as a laminate foil, or by sputtering or by plating or by a combination of sputtering and plating, and then pattering in a mask-and-etch process, for example. Electrically conductive fluids (including for example nanoparticle conductive inks) may be printed, for example by screen printing or stencil printing or by deposition from a jet or from an array of jets; or may be applied by direct transfer using a patterned stamp; or may be written, for example. Conductive epoxies or pastes, such as epoxies filled with metal particles (such as gold or silver, for example), may be dispensed, for example. The material for the traces may be a curable material; in such embodiments the curable material may be electrically conductive in the uncured condition, or only when cured, or in both the uncured and the cured condition.

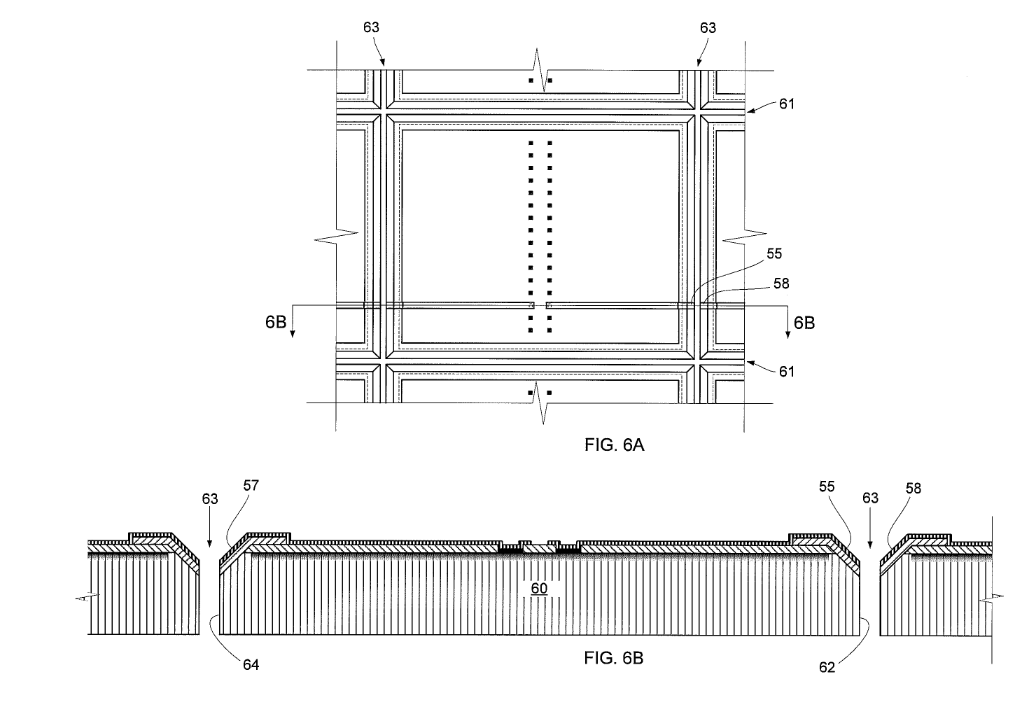

In a subsequent dicing procedure the die are singulated from the wafer, with a result as shown in FIGS. 6A, 6B. Dicing may be accomplished by cutting, for example using a dicing saw, or a laser, along dicing lines 61, 63. The semiconductor body of the resulting die 60 has sidewalls, e.g., 62, 64 (for example) (formed by the dicing procedure), generally perpendicular to the plane of the front side (and back side) of the die, and chamfered edges (formed by the groove formation). The chamfered edges are covered by the remaining portions of the groove caps, upon which portions 55, 57 (for example) of the conductive traces 54, 56 remain. Thin edges of the groove caps and of the conductive traces 55, 57 are exposed, along with the sidewalls 62, 64, by the dicing procedure.

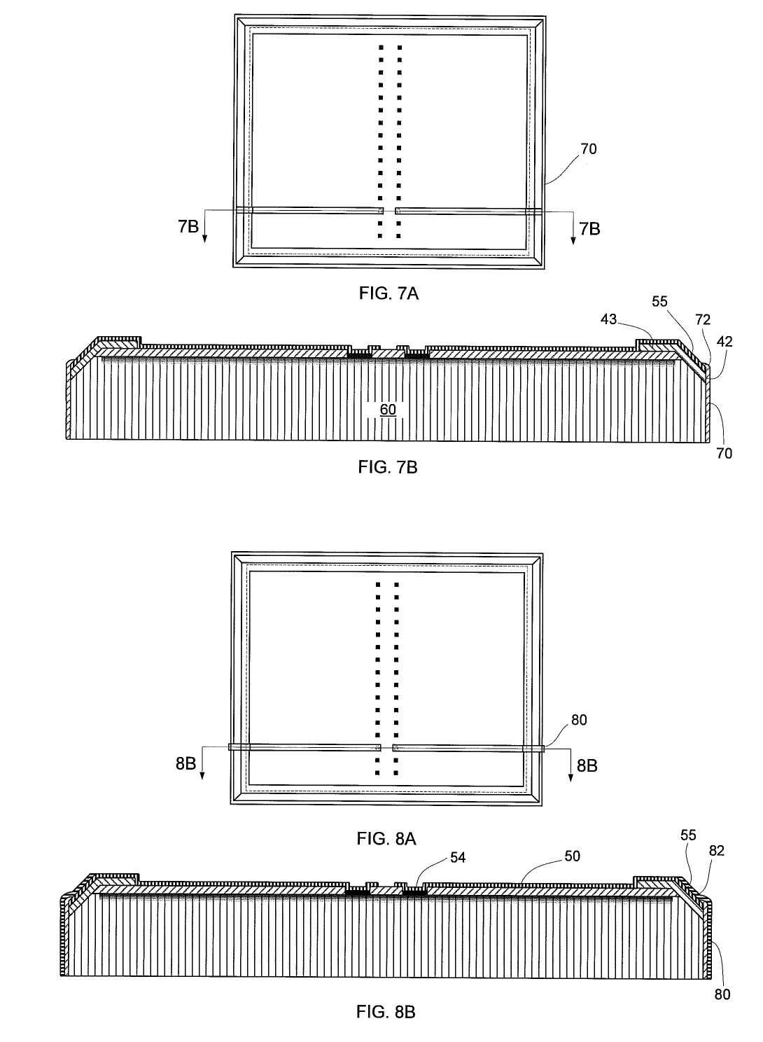

In a subsequent procedure an electrically insulative sidewall cap is formed, with a result as shown in FIGS. 7A, 7B. The sidewall cap 70 covers the exposed sidewall, along with the thin edge 42 of the remaining portion of the groove cap and the thin edge 72 of the conductive trace portion 55 on the chamfer. The sidewall cap 70 may extend, as shown at 72, onto the surface of the conductive trace portion 55. The sidewall cap may be formed as a patterned layer of a dielectric material. Suitable materials for the sidewall cap include, for example, a polymer that may be deposited or coated in a liquid phase, such as for example a polyimide/BT/epoxy/LCP that may or may not be directly photoimageable; a polymer that may be deposited in vapor phase, such as a parylene; or a liquid phase chemically deposited glass such as a sol-gel silica, for example.

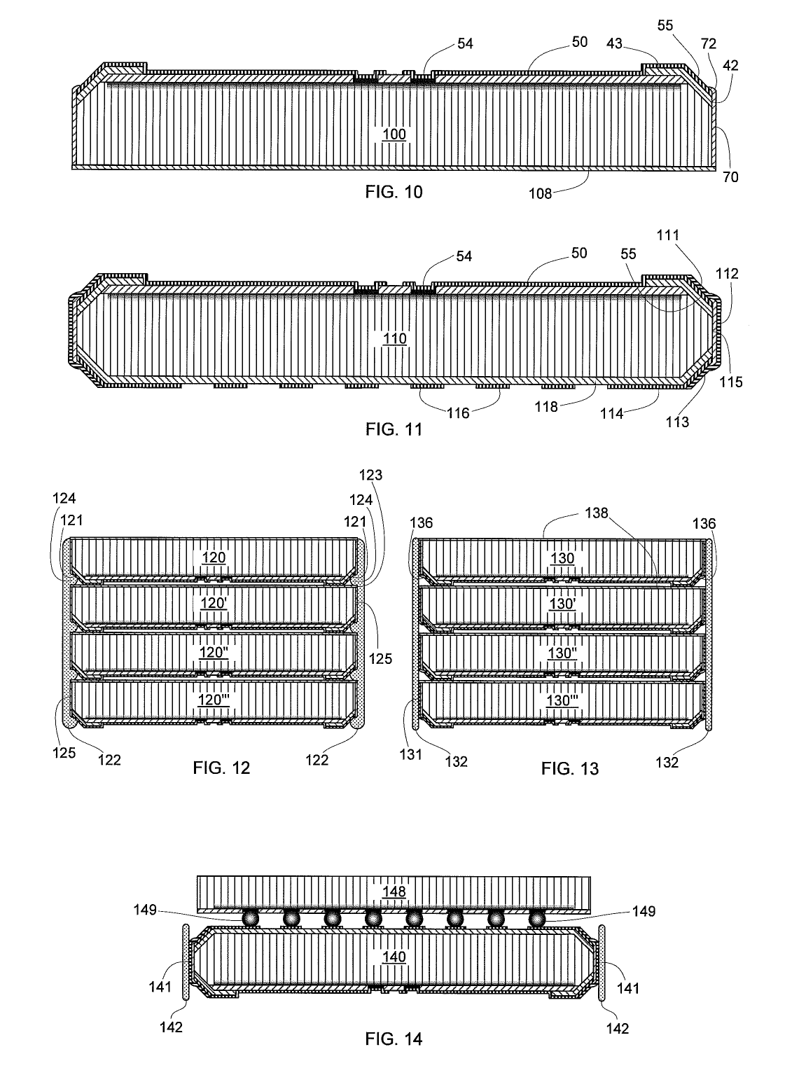

A construct as in FIGS. 7A, 7B, including a die having conductive traces electrically connected to an interconnect pad and extending over the chamfer at the front edge of the die, can be stacked and electrically interconnected with other constructs, which may include other similar constructs. FIG. 10 shows such a construct, including a die 100 configured generally as in FIG. 7B, provided with a back side insulation 108, and FIG. 12 shows a stack of four such constructs including die 120, 120′, 120″, 120′″ each as in FIG. 10, interconnected by vertical interconnects 122. In this example, interconnects 122 are formed of an interconnect material that is deformable to at least a limited extent when applied to the stack, so that a small amount 124 of the interconnect material flows or deforms into the space between adjacent die edges and makes contact with the trace over the chamfer as shown for example at 124. The sidewalls of the die are electrically insulated from the interconnects 122 by the sidewall caps 70 (e.g., at 125) and the back edges of the die are electrically insulated from the interconnects 122 by the backside insulation 108 (e.g., at 123). The deformable interconnect material may be curable; suitable materials include, for example polymers filled with conductive particles (for example, particles of metal such as gold, copper, silver), such as conductive epoxies.

The construct may be further provided with a conductive trace extending over the sidewalls.

In a subsequent procedure patterned sidewall electrically conductive traces are formed, with a result as shown in FIGS. 8A, 8B. The sidewall trace includes a generally vertical portion 80 and a portion 82 that is in electrical contact with the conductive trace portion 55 on the chamfer. The resulting die interconnect provides for electrical continuity from the connection 54 at the die pad to and over the chamfered die edge by way of the trace 50, 55, and around to the sidewall of the die by way of the sidewall trace 82, 80. Accordingly, direct access at the die sidewall is provided for vertical die-to-die interconnection in a die stack, and for vertical die-to-substrate (or die stack-to-substrate) interconnection.

The sidewall traces may be formed of any of the various materials, and by any of the various processes, that are used for the front side traces running from the pads to the groove. The sidewall traces may be of the same material as, or a different material from that of the front side traces, and may or may be formed using the same or a different procedure. The materials and the procedures should be selected to ensure good electrical connection between the front side traces and the sidewall traces.

As noted previously, the wafer may be thinned by backgrinding at an earlier stage in the process and, particularly, at a stage prior to dicing. Or, thinning may be carried out following the dicing procedure. If a dice-before-grind sequence is followed, it may optionally be preferable to thin prior to formation of the of the sidewall traces, to avoid damage to traces that might result from grinding.

The chamfer configuration can provide for shallower angles for wraparound of the conductive material at the die edge. Moreover, the surface of the chamfer is visible both in a view of the front side of the die and in a view of the sidewall of the die. This can provide for improved deposition of materials both on the front and on the sidewall of the die, during formation for example of the front traces and the sidewall traces.

Additionally, wraparound conductive traces are subject to stress where they are constructed over edges formed at surfaces that meet at a sharp angle. The stress can be reduced (for example where the trace is made using a conductive epoxy) where the surfaces meet at a shallower angle, and the chamfer provides for a shallower angle.

Optionally, a dielectric material may be applied to one or more surfaces of the resulting die, for mechanical protection and to maintain electrical isolation where required. A conformal coating may be applied, for example as described in U.S. application Ser. No. 11/016,558, which is hereby incorporated by reference; optionally the coating may cover all the surfaces of the die, with openings formed over areas of the conductive traces where electrical interconnection (or electrical contact for testing the die) is required.

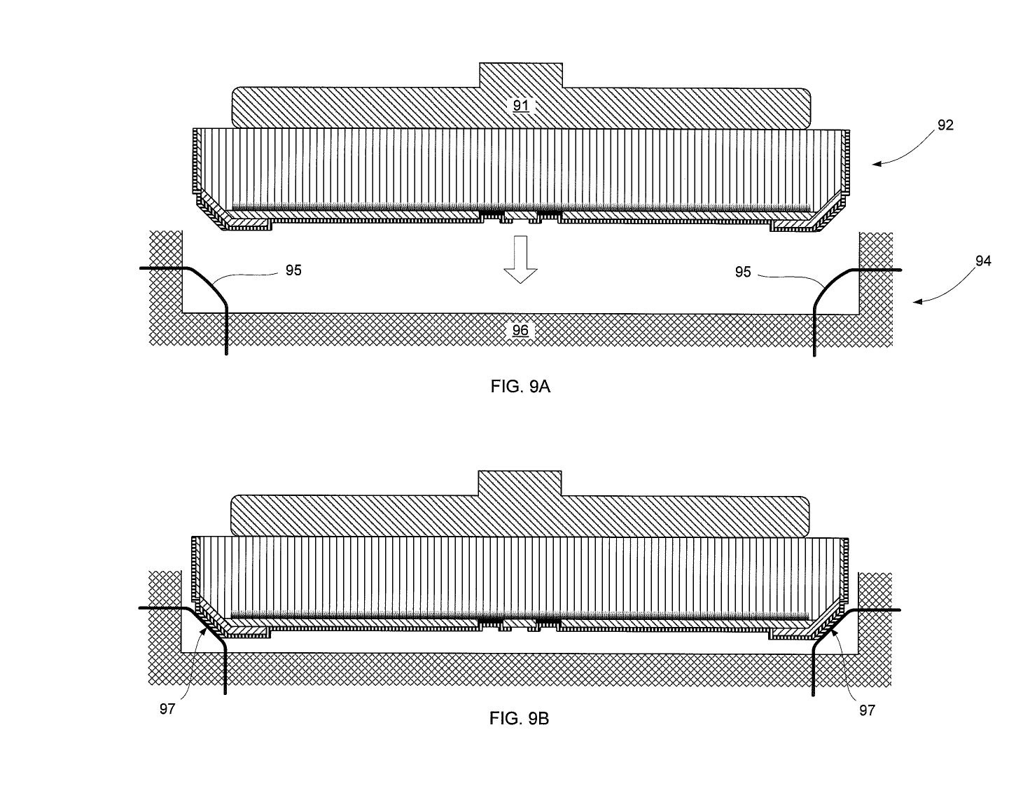

The resulting die, provided with interconnect on a chamfered edge, may be readily tested using a test socket having contacts configured to contact the angled portions of the respective traces. Such a test socket, and use of it, is shown diagrammatically in FIGS. 9A, 9B. The test socket 94 includes a base 96 of an electrically insulative material provided with resilient contacts 95. The die 92 is held by a tool 91 such as a pick-and-place tool, and aligned with the test socket so that when the die 92 is moved toward the socket the contacts touch the interconnects on the die as indicated at 97 in FIG. 9B. The contacts 95 are connected with test circuitry (not shown in the FIGs.) configured to apply electrical potentials and/or to supply electrical currents at the various interconnects suitable for testing the die. No contact of the test equipment with the die pads is necessary for such testing.

Two or more of such die may be stacked one over another, with a suitable dielectric between adjacent die (or a dielectric coating on at least one of the adjacent die surfaces); and the die may be readily interconnected (die-to-die, die-to-substrate; die stack-to-substrate) by forming interconnects directly on the traces, either at the vertical sidewalls or at the chamfer or at both the sidewalls and the chamfer. FIG. 13 shows a stack of four constructs, including die 130, 130′, 130″, 130′″ each as in FIG. 8B and each provided with a backside insulation 138, interconnected by vertical interconnects 132. In this example, the interconnects may be formed of a deformable interconnect material so that a small amount of the interconnect material flows or deforms into the space between adjacent die edges and makes contact with the trace, e.g., 136 over the chamfer (as described generally with reference to FIG. 12). Or, as shown in FIG. 13, interconnects 132 may be formed of a material that contacts sidewall conductive trace as shown for example at 131, and does not deform significantly into the space between adjacent die edges. The traces on each die are electrically insulated from the backside of adjacent die by the backside insulation 138. The interconnect material may be a metal tape or wire, for example.

The wraparound conductive traces may additionally be extended to and around the backside edges of the die. FIG. 11 shows a die 110 provided with chamfers at both the front edges and the back edges, and provided with conductive traces at the front side and the back side and the sidewalls, and extending around the chamfers at both the front and back edges. Such a construct can be made, for example, by turning the wafer over at the stage shown in FIGS. 6A, 6B, and then carrying out on the backside of the wafer procedures of forming backside grooves, forming an insulation 118 over the backside and in the backside grooves, forming patterned conductive traces 114,116 over the backside insulation and into the grooves; forming sidewall caps 115, and forming sidewall traces. The sidewall trace includes a generally vertical portion 112, a portion 111 that is in electrical contact with the conductive trace portion 55 on the front chamfer, and a portion 113 that is in electrical contact with the conductive trace 114 on the back chamfer. The resulting die interconnect provides for electrical continuity from the connection 54 at the die pad to and over the chamfered die edge by way of the trace 50, 55, around to the sidewall of the die by way of the sidewall trace 111, 112, 113, around to the backside trace 114. Direct access at the die sidewall is provided for vertical die-to-die interconnection in a die stack, and for vertical die-to-substrate (or die stack-to-substrate) interconnection. Moreover, direct access at the backside of the die is provided for surface interconnection to another die or to a substrate, by way of interconnect pads 116 in the patterned backside conductive traces.

A two-die stack including a die stacked over a construct as in FIG. 11 is shown by way of example in FIG. 14. In this example a die 140 construct is made generally as shown in FIG. 11, and provided with vertical interconnects 142 in contact with sidewall traces 141. A second die 148 is mounted upon the backside of the die 140, in a flip-chip manner by mating balls or bumps 149 with pads on the conductive traces at the backside of the die 140. This assembly may be mounted upon underlying circuitry, for example, or stacked over other die or die stacks, and electrically interconnected by way of the vertical interconnects 142.

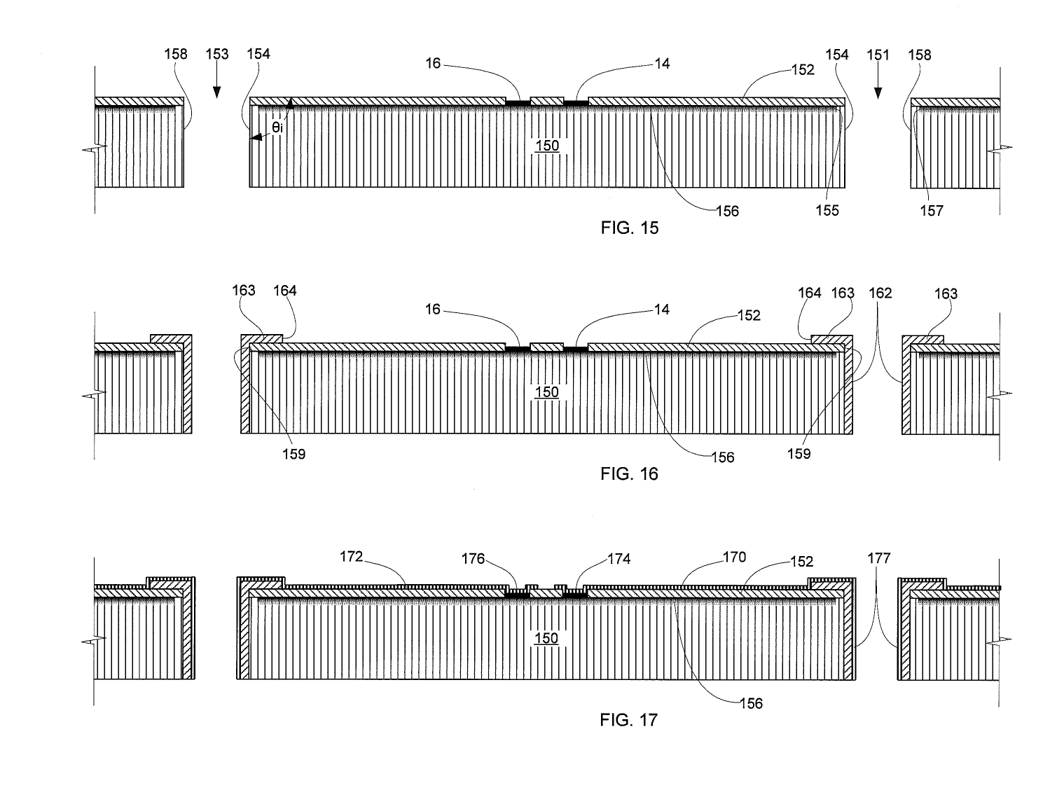

In the embodiments illustrated above the edge is chamfered at the conjunction of the front side of the die and the die sidewall. In other embodiments the die edge is not chamfered. Two such embodiments are shown by way of example in FIGS. 15, 16, 17 and 18, 19, 20.

Referring to FIG. 15, a wafer is provided as in FIG. 2B, and trenches 151, 153 are formed in the saw streets. The trenches define die sidewalls 154, 158 which, in this example, are generally perpendicular to the front side of the wafer; that is, the plane of the sidewalls is at an inside angle θi about 90°. The trenches cut at least through the passivation layer 152 and into the semiconductor material 150 of the wafer. They are shown in these examples as passing fully through the semiconductor material of the wafer; in practice the trenches may not pass through the entire wafer thickness. Where, for example the trenches are formed prior to thinning the wafer, the trenches may be formed to a depth in the wafer at least as great as the desired die thickness, so that a later backgrind procedure results in singulation of the die. Or where, for example, the wafer is thinned to the desired die thickness prior to trench formation, the trenches may stop at less than the die thickness and may be cut through in a subsequent procedure following formation of the electrically conductive interconnect traces. The trenches are located outside the limits 155, 157 of the active regions (e.g., 156) of the respective chips, so that the trenches do not impact the circuitry of the chips.

The trenches may be formed by cutting, using for example a saw or grinding tool, or for example using a laser. Where the grooves are cut, more than one pass of the cutting tool may be employed. Or, the trenches may be formed by chemical etching, for example.

In a later procedure a dielectric cap is formed in the trenches, with a result as shown for example in FIG. 16. A portion of the cap 162 covers the walls of the trench (that is, the sidewalls 154,158 of the die), and portions 163 of the cap overlap at least the edges 159 of the underlying passivation layer 152, but the cap does not cover the interconnect pads 14, 16.

The cap may be formed as a patterned layer of dielectric cap material. It may be formed by deposition and patterned removal (for example, by etch or by laser ablation), or by a patterned deposition (for example by direct write or print), or by a combination of patterned deposition and etch. Suitable materials for the dielectric cap material include, for example, a polymer that may be deposited or coated in a liquid phase, such as for example a polyimide/BT/epoxy/LCP that may or may not be directly photoimageable; a polymer that may be deposited in vapor phase, such as a parylene; or a liquid phase chemically deposited glass such as a sol-gel silica, for example.

In a subsequent procedure patterned electrically conductive traces are formed, contacting the interconnect pads 14,16 and extending into the capped trenches, with a result as shown for example in FIG. 17. As the FIG. illustrates, conductive traces 170, 172 contact die pads 14, 16 at 174, 176, respectively, and extend into the capped trenches. Additional such traces (omitted from FIG. 17) are formed in contact with other die pads and extend into the grooves.

The traces may end at or near the die edge, or may be formed to a small distance over the die edge, or (as shown in this example) may be formed well into the trench, onto the capped die sidewalls.

The conductive traces may be formed of any of a variety of electrically conductive materials, including metals and metal alloys, conductive inks, and conductive epoxies, for example. The conductive traces may be formed by any of a variety of techniques, selected as appropriate according to the material. Metal traces (gold, aluminum, copper) can be formed by applying a metal film (for example by sputtering or evaporative deposition) or metallization such as a laminate foil, or by sputtering or by plating or by a combination of sputtering and plating, and then pattering in a mask-and-etch process, for example. Electrically conductive fluids (including for example nanoparticle conductive inks) may be printed, for example by screen printing or stencil printing or by deposition from a jet or from an array of jets; or may be applied by direct transfer using a patterned stamp; or may be written, for example. Conductive epoxies or pastes, such as epoxies filled with metal particles (such as gold or silver, for example), may be dispensed, for example. The material for the traces may be a curable material; in such embodiments the curable material may be electrically conductive in the uncured condition, or only when cured, or in both the uncured and the cured condition.

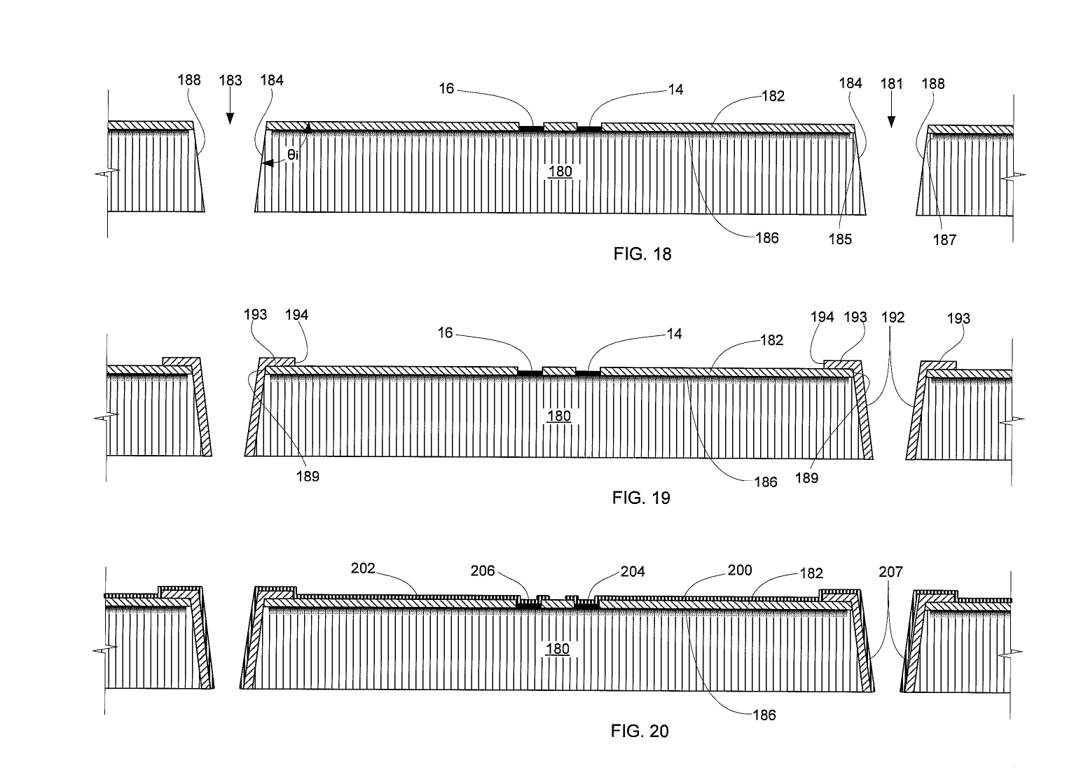

The example shown in FIGS. 18-20 is constructed in a similar manner, and using similar materials and techniques. Referring now to FIG. 18, a wafer is provided as in FIG. 2B, and trenches 181, 183 are formed in the saw streets. The trenches define die sidewalls 184, 188. The trenches in this example have a generally trapezoidal sectional profile, as the FIGs. show, and accordingly the sidewalls are at an angle to the front side of the wafer; that is, the plane of the sidewalls is at an inside angle θi greater than (and may be only slightly greater than) about 90°. The trenches cut at least through the passivation layer 182 and into the semiconductor material 180 of the wafer. They are shown in these examples as passing fully through the semiconductor material of the wafer; in practice the trenches may not pass through the entire wafer thickness. Where, for example the trenches are formed prior to thinning the wafer, the trenches may be formed to a depth in the wafer at least as great as the desired die thickness, so that a later backgrind procedure results in singulation of the die. Or where, for example, the wafer is thinned to the desired die thickness prior to trench formation, the trenches may stop at less than the die thickness and may be cut through in a subsequent procedure following formation of the electrically conductive interconnect traces. The trenches are located outside the limits 185, 187 of the active regions (e.g., 186) of the respective chips, so that the trenches do not impact the circuitry of the chips.

In a later procedure a dielectric cap is formed in the trenches, with a result as shown for example in FIG. 19. A portion of the cap 192 covers the walls of the trench (that is, the sidewalls 184, 188 of the die), and portions 193 of the cap overlap at least the edges 189 of the underlying passivation layer 182, but the cap does not cover the interconnect pads 14, 16.

In a subsequent procedure patterned electrically conductive traces are formed, contacting the interconnect pads 14, 16 and extending into the capped trenches, with a result as shown for example in FIG. 20. As the FIG. illustrates, conductive traces 200, 202 contact die pads 14, 16 at 204, 206, respectively, and extend into the capped trenches. Additional such traces (omitted from FIG. 20) are formed in contact with other die pads and extend into the grooves.

The traces may end at or near the die edge, or may be formed to a small distance over the die edge, or (as shown in this example) may be formed well into the trench, onto the capped die sidewalls.

### Other Embodiments are Within the Invention

For example, a peripheral pad die may be treated as described and shown for a center pad die. Because the pads are nearer the edges of the active region of the die (and, accordingly, nearer the saw streets), the distance between the front traces and the grooves will be shorter on a peripheral pad die than on a center pad die.

And, for example, the front traces need not be oriented perpendicularly to the groove, nor need the traces follow a straight path or the shortest path from the pads to the grooves. Moreover, the traces from any particular pad may be routed to the groove at an edge (the third or the fourth edge) other than a groove that runs parallel to the rows of pads. Not all the pads on a given die need be provided with conductive traces.

All patents and patent applications referred to herein are hereby incorporated herein by reference.

We claim:

1. A stackable integrated circuit device, including an integrated circuit die having interconnect pads on an active (front) side, the die having a front side edge at the conjunction of the front side of the die and a sidewall of the die and a back side edge at the conjunction of back side of the die and the sidewall, the die comprising a conductive trace which is electrically connected to an interconnect pad and which extends over the front side edge of the die.

2. The device of claim 1 wherein the conductive trace further extends over the sidewall.

3. The device of claim 1 wherein the conductive trace further extends over the back side edge of the die and over the back side of the die.

4. The device of claim 1, further comprising a trace at the back side of the die.

5. The device of claim 4 wherein the backside trace extends over the back side edge.

6. The device of claim 1 wherein the die has a chamfered edge at the conjunction of the front side of the die and a sidewall of the die, and wherein the conductive trace extends over the chamfer at the chamfered edge of the die.

7. The device of claim 6 wherein the conductive trace further extends over the sidewall.

8. The device of claim 6 wherein the die has chamfered edge at the conjunction of the back side of the die and a sidewall of the die, and wherein the conductive trace extends over the back edge chamfer.

9. The device of claim 8, further comprising a conductive trace at the back side of the die.

10. The device of claim 9 wherein the backside trace extends over the back edge chamfer.

11. The device of claim 1 wherein the die includes both a front edge chamfer and a back edge chamfer at one of more of the sidewalls, and a conductive trace which is electrically connected to an interconnect pad extends over the front edge chamfer, the sidewall, the back edge chamfer and the die backside.

12. The device of claim 1 wherein the die further comprises an electrical insulation between the conductive trace and the die edge.

13. The device of claim 1 wherein the die further comprises an electrical insulation between the conductive trace and the die sidewall.

14. The device of claim 1 wherein the interconnect pad is one of a row of pads arranged near a centerline of the die.

15. The device of claim 1 wherein the interconnect pad is one of a row of pads arranged near an edge of the die.

16. The device of claim 15 wherein the conductive trace extends to a die edge that is parallel to the row of pads.

17. The device of claim 15 wherein the conductive trace extends to a die edge other than a die edge that is parallel to the row of pads.

18. A test socket for testing a stackable integrated circuit device as described above, comprising an electrically insulative base and electrically conductive contacts, wherein each contect is arranged to make electrical contact with a portion of the conductive trace at the chamfer, and wherein the contacts are connected to test circuitry.

19. A method for testing a stackable integrated circuit device as in claim 1, comprising providing a test socket comprising an electrically insulative base and electrically conductive contacts, wherein each contect is arranged to make electrical contact with a portion of the conductive trace at the chamfer, and wherein the contacts are connected to test circuitry, moving the device toward the test socket so that the contacts make electrical contact with respective traces at the chamfer; and activating the test circuitry.

20. A method for making a stackable integrated circuit device, comprising:
providing a wafer including a plurality of semiconductor die each having edges bounded by saw streets and each having an interconnect pad on an active (front) side;
forming a trench in the street, the trench defining die edges and die sidewalls; and
forming an electrically conductive trace that is electrically connected to the pad and that extends to one of the edges.

21. The method of claim 20, further comprising forming an electrical insulation between the conductive trace and the die edge.

22. The method of claim 20 wherein the trench has a generally rectangular sectional profile, so that the resulting die sidewalls are generally perpendicular to the plane of the die front side.

23. The method of claim 22 wherein the trench has a generally trapezoidal sectional profile, so that an inside angle formed at the conjunction of the die front side and the resulting sidewalls is greater than about 90°.

24. The method of claim 20 wherein forming the electrically conductive trace comprises forming the trace to extend over the edge.

25. The method of claim 20 wherein forming the electrically conductive trace comprises forming the trace to extend over the edge and over the die sidewall.

26. The method of claim 25, further comprising forming an electrical insulation between the conductive trace and the die sidewall.

27. A method for making a stackable integrated circuit device, comprising:
providing a wafer including a plurality of semiconductor die each having edges bounded by saw streets and each having an interconnect pad on an active (front) side;
forming a chamfer at a die edge;
forming an electrically conductive trace that is electrically connected to the pad and that extends over the chamfer; and
cutting the wafer to form a sidewall.

28. The method of claim 27, further comprising forming an electrically conductive sidewall trace that is electrically connected to the conductive trace over the chamfer and that extends over the sidewall.

29. The method of claim 29, further comprising forming an electrical insulation between the conductive sidewall trace and the sidewall.

30. An assembly comprising a stack of devices as in claim 1, interconnected die-to-die by a conductive element that is electrically connected to the conductive trace on at least two of the stacked die.

31. An assembly comprising a stack of devices as in claim 1, interconnected to underlying circuitry on a support by a conductive element that is electrically connected to the conductive trace on at least one of the stacked die and to a site on the underlying circuitry.
